(19) United States
(12) Patent Application Publication
(10) Pub. No.: US 2021/0408319 A1
(43) Pub. Date: Dec. 30, 2021

(54) AVALANCHE PHOTODETECTOR WITH DEEP-LEVEL-ASSISTED IMPACT IONIZATION

(71) Applicant: MCMASTER UNIVERSITY, Hamilton (CA)

(72) Inventors: ANDREW PETER KNIGHTS, DUNDAS (CA); DAVID E. HAGAN, MISSISSAUGA (CA)

(21) Appl. No.: 17/356,777

(22) Filed: Jun. 24, 2021

Related U.S. Application Data
(60) Provisional application No. 63/043,598, filed on Jun. 24, 2020.

(51) Int. Cl. H01L 31/107

(52) U.S. Cl. CPC H01L 31/1075

(57) ABSTRACT

Avalanche photodetector devices and methods of use thereof are provided that incorporate deep levels to increase secondary carrier generation via impact ionization under application of a reverse bias. An avalanche photodetector device may include p+ and n+ regions, an intermediate semiconductor absorption region provided therebetween, and at least one semiconductor region residing between the p+ and n+ regions that incorporates deep levels. When light is incident on the device such that the absorption depth of the light extends into the intermediate semiconductor absorption region, a photocurrent is produced under a reverse bias includes both photocarriers generated within the intermediate semiconductor absorption region and secondary carriers released from the deep levels via impact ionization. The deep levels may facilitate an increased sensitivity, relative to a device absent of deep levels, via a deep-level ionization energy threshold that is less than a threshold for conventional impact ionization across a bandgap.

### CROSS-REFERENCE TO RELATED APPLICATION

This application claims priority to U.S. Provisional Patent Application No. 63/043,598, titled “AVALANCHE PHOTODETECTOR WITH DEEP-LEVEL-ASSISTED IMPACT IONIZATION” and filed on Jun. 24, 2020, the entire contents of which is incorporated herein by reference.

### BACKGROUND

The present disclosure relates to avalanche photodetectors. In some aspects, the present disclosure relates to deep-level doped silicon avalanche photodetectors.

The avalanche photodetector (APD) is a widely deployed semiconductor device used for the detection of optical signals with relatively low power. By application of a large electric field, primary photocarriers in the device can be accelerated such that they create additional carriers in an “avalanche” effect. The most commonly used material for the fabrication of APDs is silicon.

### SUMMARY

Avalanche photodetector devices and methods of use thereof are provided that incorporate deep levels to increase secondary carrier generation via impact ionization under application of a reverse bias. An avalanche photodetector device may include p+ and n+ regions, an intermediate semiconductor absorption region provided therebetween, and at least one semiconductor region residing between the p+ and n+ regions that incorporates deep levels. When light is incident on the device such that the absorption depth of the light extends into the intermediate semiconductor absorption region, a photocurrent is produced under a reverse bias includes both photocarriers generated within the intermediate semiconductor absorption region and secondary carriers released from the deep levels via impact ionization. The deep levels may facilitate an increased sensitivity, relative to a device absent of deep levels, via a deep-level ionization energy threshold that is less than a threshold for conventional impact ionization across a bandgap.

Accordingly, in one aspect, there is provided a method of performing photodetection with an avalanche photodetector device, the method comprising:

providing an avalanche photodetector device comprising a p-doped semiconductor region, an n-doped semiconductor region, and an intermediate semiconductor absorption region residing between the n-doped semiconductor region and the p-doped semiconductor region, wherein at least one semiconductor region residing between the p-doped semiconductor region and the n-doped semiconductor region comprises deep levels;

while applying a reverse bias to the avalanche photodetector device, directing incident light onto the avalanche photodetector device, the incident light comprising photons having an energy exceeding a bandgap of the intermediate semiconductor absorption region, wherein an absorption depth of the incident light extends into the intermediate semiconductor absorption region, such that a photocurrent is produced comprising photocarriers generated within the intermediate semiconductor absorption region and secondary carriers released from the deep levels via impact ionization.

According to an example implementation of the method, the p-doped semiconductor region is a p-doped semiconductor layer, the n-doped semiconductor region is an n-doped semiconductor layer, and the intermediate semiconductor absorption region is an intermediate semiconductor absorption layer.

The intermediate semiconductor absorption layer may comprise at least a portion of the deep levels. The incident light may enter the avalanche photodetector device through an external surface, and wherein a concentration of deep levels within the intermediate semiconductor absorption layer is lower within a first portion of the intermediate semiconductor absorption layer that is closer to the external surface than within a second portion of the intermediate semiconductor absorption layer that is further from the external surface. The first portion may have a concentration of deep levels that is less than 1×10¹⁴ cm⁻³ and wherein the second portion has a concentration of deep levels that is greater than 1×10¹⁴ cm⁻³ and less than 1×10¹⁹ cm⁻³.

In some example implementations of the method, the p-doped semiconductor layer is a first p-doped semiconductor layer, and wherein the avalanche photodetector device further comprises:

a second p-doped semiconductor layer having a doping concentration less than the first p-doped layer, the second p-doped semiconductor layer residing between the n-doped semiconductor layer and the intermediate semiconductor absorption layer;

a semiconductor avalanche layer residing between the n-doped semiconductor layer and the second p-doped semiconductor layer;

wherein a thickness of the intermediate semiconductor absorption layer exceeds a thickness of the semiconductor avalanche layer, such that impact ionization occurs predominantly within the semiconductor avalanche layer; and

wherein the semiconductor avalanche layer comprises at least a portion of the deep levels.

A concentration of deep levels in the semiconductor avalanche layer may exceed a concentration of deep levels in the intermediate semiconductor absorption layer. A concentration of the deep levels within the semiconductor avalanche layer may lie between 1×10¹⁴ cm⁻³ and 1×10¹⁹ cm⁻³. A concentration of the deep levels within the intermediate semiconductor absorption layer may be less than 1×10¹⁴ cm⁻³.

The incident light may be incident on the avalanche photodetector device through an external surface that is closer to the intermediate semiconductor absorption layer than to the semiconductor avalanche layer. The incident light may be incident on the avalanche photodetector device such that the incident light encounters the intermediate semiconductor absorption layer without first passing through the semiconductor avalanche layer.

In some example implementations of the method, a concentration of the deep levels within the at least one semiconductor region lies between 1×10¹⁴ cm⁻³ and 1×10¹⁹ cm⁻³

In some example implementations of the method, the p-doped semiconductor region is laterally offset from the n-doped semiconductor region, such that at least a portion of the intermediate semiconductor absorption region resides between the p-doped semiconductor region and the n-doped semiconductor region.

In another aspect, there is provided an avalanche photodetector device comprising:

a p-doped semiconductor layer;

an n-doped semiconductor layer; and

an intermediate semiconductor absorption layer residing between said n-doped semiconductor layer and said p-doped semiconductor layer;

wherein at least one semiconductor region residing between said p-doped semiconductor layer and said n-doped semiconductor layer comprises deep levels, such that when incident light having a photon energy exceeding a band gap of said intermediate semiconductor absorption layer is directed onto said avalanche photodetector device and a suitable reverse bias is applied to said avalanche photodetector device, a photocurrent is produced comprising photocarriers generated within said intermediate semiconductor absorption layer and secondary carriers released from the deep levels via impact ionization.

In some example implementations of the method, the intermediate semiconductor absorption layer comprises at least a portion of the deep levels.

The device may further comprise an external surface configured to receive the incident light, wherein a concentration of deep levels within the intermediate semiconductor absorption layer is lower within a first portion of the intermediate semiconductor absorption layer that is closer to the external surface than within a second portion of the intermediate semiconductor absorption layer that is further from the external surface.

The first portion may have a concentration of deep levels that is less than 1×10¹⁴ cm⁻³ and wherein the second portion has a concentration of deep levels that is greater than 1×10¹⁴ cm⁻³ and less than 1×10¹⁹ cm⁻³.

In some implementations of the device, the p-doped semiconductor layer is a first p-doped semiconductor layer, and wherein the avalanche photodetector device further comprises:

a second p-doped semiconductor layer having a doping concentration less than the first p-doped layer, the second p-doped semiconductor layer residing between the n-doped semiconductor layer and the intermediate semiconductor absorption layer;

a semiconductor avalanche layer residing between the n-doped semiconductor layer and the second p-doped semiconductor layer;

wherein a thickness of the intermediate semiconductor absorption layer exceeds a thickness of the semiconductor avalanche layer, such that impact ionization occurs predominantly within the semiconductor avalanche layer under application of the suitable reverse bias; and

wherein the semiconductor avalanche layer comprises at least a portion of the deep levels.

A concentration of deep levels in the semiconductor avalanche layer may exceed a concentration of deep levels in the intermediate semiconductor absorption layer. A concentration of the deep levels within the semiconductor avalanche layer may lie between 1×10¹⁴ cm⁻³ and 1×10¹⁹ cm⁻³. A concentration of the deep levels within the intermediate semiconductor absorption layer may be less than 1×10¹⁹ cm⁻³

The device may include an external surface configured to receive the incident light, wherein the external surface is closer to the intermediate semiconductor absorption layer than to the semiconductor avalanche layer.

In some implementations of the device, a concentration of the deep levels within the at least one semiconductor region lies between 1×10¹⁴ cm⁻³ and 1×10¹⁹ cm⁻³.

In another aspect, there is provided a method of performing photodetection with an avalanche photodetector device, the method comprising:

providing an avalanche photodetector device comprising a p-doped semiconductor region, an n-doped semiconductor region, and an intermediate semiconductor absorption region residing between the n-doped semiconductor region and the p-doped semiconductor region, and an avalanche semiconductor region residing between the n-doped semiconductor region and the p-doped semiconductor region, wherein the intermediate semiconductor absorption region and the avalanche semiconductor region each comprise deep levels;

while applying a reverse bias to the avalanche photodetector device, directing incident light onto the avalanche photodetector device, the incident light comprising photons having an energy less than a bandgap of the intermediate semiconductor absorption region, wherein an absorption depth of the incident light extends into the intermediate semiconductor absorption region, such that a photocurrent is produced comprising photocarriers generated by deep-level-mediated absorption within the intermediate semiconductor absorption region and by secondary carriers released from the deep levels within the avalanche semiconductor region via impact ionization.

In another aspect, there is provided an avalanche photodetector device comprising:

a p-doped semiconductor layer;

an n-doped semiconductor layer;

an intermediate semiconductor absorption layer residing between the n-doped semiconductor layer and the p-doped semiconductor layer; and

a semiconductor avalanche layer residing between the n-doped semiconductor layer and the p-doped semiconductor layer;

wherein the intermediate semiconductor absorption layer and the semiconductor avalanche layer comprise deep levels, such that when incident light having a photon energy less than a band gap of the intermediate semiconductor absorption layer is directed onto the avalanche photodetector device and a suitable reverse bias is applied to the avalanche photodetector device, a photocurrent is produced comprising photocarriers generated via deep-level-mediated absorption within the intermediate semiconductor absorption layer and by secondary carriers released from the deep levels via impact ionization within the semiconductor avalanche layer.

A further understanding of the functional and advantageous aspects of the disclosure can be realized by reference to the following detailed description and drawings.

### BRIEF DESCRIPTION OF THE DRAWINGS

Embodiments will now be described, by way of example only, with reference to the drawings, in which:

FIG. 1A illustrates the conventional avalanche process associated with impact ionization of carriers across the semiconductor bandgap.

FIG. 1B illustrates an impact ionization event in which a secondary electron is generated from a deep level via impact ionization.

FIG. 2A illustrates an example of an avalanche photodetector device in which an intermediate semiconductor absorption layer includes deep levels that contribute secondary carriers via impact ionization when above-bandgap light is absorbed and a reverse bias is applied.

FIG. 2B illustrates an example of an avalanche photodetector device in which an intermediate semiconductor absorption layer includes deep levels that contribute secondary carriers via impact ionization when above-bandgap light is absorbed and a reverse bias is applied, where a concentration of deep levels within the intermediate semiconductor absorption layer is lower within a region that is closer to an external surface onto which incident light is directed than within a region that is further from the external surface.

FIG. 2C illustrates an example of an avalanche photodetector device in which an intermediate semiconductor absorption layer includes deep levels within a subregion that is furthest from an external surface onto which incident light is directed.

FIG. 2D illustrates an example of an avalanche photodetector device in which an intermediate semiconductor absorption layer includes deep levels that contribute secondary carriers via impact ionization when above-bandgap light is absorbed and a reverse bias is applied, where a concentration of deep levels within the intermediate semiconductor absorption layer is graded and increases with depth from an interface that is closest to an external surface onto which incident light is directed.

FIG. 3 illustrates an example of an avalanche photodetector device including an intermediate semiconductor absorption layer configured to absorb above-bandgap light and an avalanche semiconductor layer that includes deep levels, where the deep levels contribute secondary carriers via impact ionization when above-bandgap light is absorbed and a reverse bias is applied.

FIG. 4 illustrates an example of an avalanche photodetector device in which an intermediate semiconductor absorption region includes deep levels that contribute secondary carriers via impact ionization when above-bandgap light is absorbed and a reverse bias is applied.

FIGS. 5A and 5B plot the internal responsivity of a deep level implanted silicon avalanche photodetector when detecting above-bandgap light, with deep levels generated via ion implantation of boron ions at an energy of 70 keV, and doses of 3×10¹¹ cm⁻² and 1×10¹² cm⁻², respectively, demonstrating an improvement of responsivity with increasing deep level implantation dose (and associated deep level concentration).

FIG. 6 shows a cross-sectional view of an example deep-level-implanted avalanche photodetector device that employs deep levels for both sub-bandgap absorption and secondary carrier generation via impact ionization.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. Unless otherwise specified, the terms “about” and “approximately” mean plus or minus 25 percent or less.

It is to be understood that unless otherwise specified, any specified range or group is as a shorthand way of referring to each and every member of a range or group individually, as well as each and every possible sub-range or sub-group encompassed therein and similarly with respect to any sub-ranges or sub-groups therein. Unless otherwise specified, the present disclosure relates to and explicitly incorporates each and every specific member and combination of sub-ranges or sub-groups.

As used herein, the term “on the order of”, when used in conjunction with a quantity or parameter, refers to a range spanning approximately one tenth to ten times the stated quantity or parameter.

Unless defined otherwise, all technical and scientific terms used herein are intended to have the same meaning as commonly understood to one of ordinary skill in the art. Unless otherwise indicated, such as through context, as used herein, the following terms are intended to have the following meanings:

As used herein, the phrase “deep level” pertains to the energy level of a dopant or defect for which the energy level separation relative to a band edge is at least 3 times kT, where k is Boltzman's constant and T is temperature.

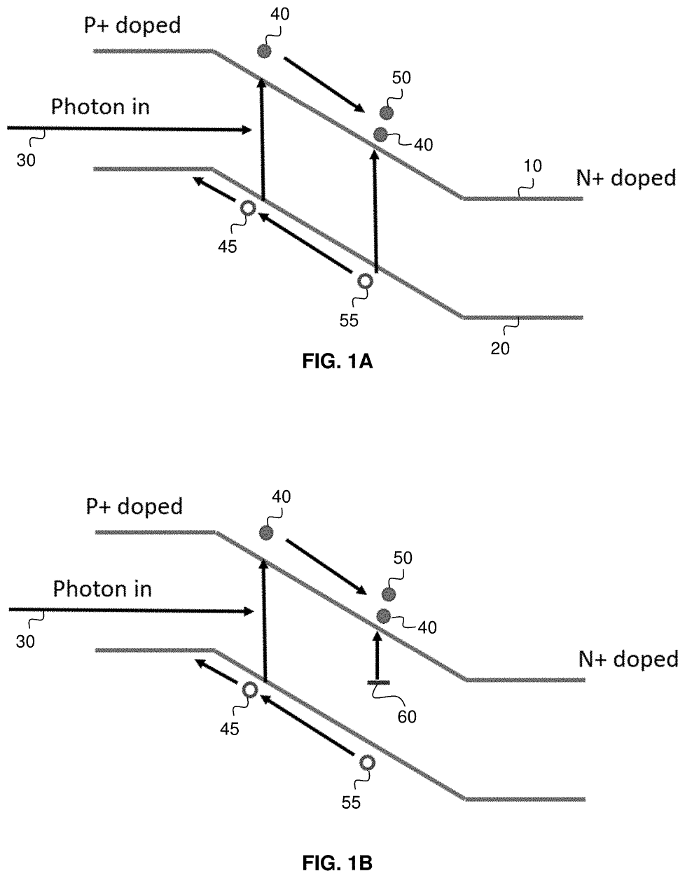

FIG. 1A illustrates the conventional process of avalanche photodetection in an avalanche photodetector device. The figure shows the conduction 10 and valence 20 bands when the device is operated under reverse bias. A photon 30, having an energy exceeding the semiconductor bandgap, is incident from the left, is absorbed by the semiconductor, and generates a primary electron-hole pair (40, 45). The primary hole 45, in this case, is collected before it can cause a secondary ionization. However, the primary electron 40 drifts under application of the reverse bias and causes an ionization event, creating a secondary electron hole pair (50, 55). Multiple ionization events may take place creating a large gain. The ionization process is dependent on the energy required to create the electron-hole pair, which may be considered to be the bandgap of the semiconductor.

While conventional APDs are capable of detecting above-bandgap light, the incorporation of deep levels in silicon has been demonstrated to facilitate generation of electron-hole primary photocarriers via sub-bandgap absorption involving the deep levels. When a suitable reverse bias is applied to such a device, the photogenerated carriers are capable of undergoing avalanche multiplication via impact ionization.

The present inventors, when experimenting with such deep-level-implanted silicon APDs for the detection of sub-bandgap light, observed that the avalanching process took place at a significantly lower electric field than when operating a conventional silicon APD for the detection of above-bandgap light. It was hypothesized that the presence of the deep levels in such devices could lower the energy threshold for impact ionization. In other words, it was hypothesized that unlike conventional silicon APDs for which the impact ionization threshold is related to the semiconductor bandgap energy, the relevant threshold for impact ionization of a deep-level-implanted APD may be associated with energy of the deep level relative to the semiconductor band edge.

This hypothesis was explored using simulations involving the application of previously described “Lucky-Drift” theory (Kasap et al., Jnl. of Appl. Physics vol. 96 (2004) p. 2038), and fitting experimental data with an analytical model. The results led the inventors to suspect that the hypothesis may be correct and that APD devices with deep levels may have an impact ionization energy that is less than the bandgap of the semiconductor and associated instead with the energy of the deep level.

The lucky drift model leads to realization that at high fields, hot electrons do not relax momentum and energy at the same rates. Momentum relaxation is much faster than the energy relaxation. An electron can drift, being scattered by phonons, and have its momentum relaxed, which controls the drift velocity, but it can still gain energy during this drift. Stated differently, the mean free path for energy relaxation is much longer than the mean free path for momentum relaxation. The theory may be summarized using an analytical equation that may be fitted to experimental data:

$$α = ( \frac{1}{{λ}_{E}} ) exp ( - \frac{{E}_{I}}{e F {λ}_{E}} )$$

Here, α is the ionization coefficient when either electron or hole ionization dominates, λ_{E} is the mean energy relaxation length, e is the charge of an electron, E_{I} is the ionization energy required for secondary carrier generation to occur, and F is the electric field.

The present inventors, guided by this finding, realized that although the conventional use of deep levels in silicon APDs had been restricted to facilitating sub-bandgap optical absorption for photocarrier generation, deep levels could also be employed to improve the operation of APDs for the detection of above-bandgap light, e.g. to reduce a threshold for avalanche detection and/or to improve noise performance. In other words, the present inventors, armed with the discovery that deep levels appear to reduce the threshold of impact ionization, realized that deep levels could be employed in APDs as an additional means or mechanism for secondary carrier generation via impact ionization, even when the primary photocarriers are generated via above-bandgap optical absorption.

FIG. 1B illustrates the generation of secondary carriers via impact ionization involving the deep levels with a reduced energy threshold for ionization. As in FIG. 1A, the incident photon 30 generates a primary electron-hole pair (40, 45) and the primary hole 45 is collected before it can cause a secondary ionization. The primary electron undergoes drift and causes ionization, creating a secondary electron hole pair (50, 55). However, in this case the ionization takes place from an energy level 60 that is associated with a deep level and which resides within the bandgap of the semiconductor. This deep level state may be created through the lattice perturbation caused, for example, by implantation. The ionization process involving the deep level 60 in the example shown requires much less energy (approximately half) compared to the conventional impact ionization process. Accordingly, the onset of the avalanche process may occur at a fraction of the reverse bias that would have been necessary in the absence of the deep levels.

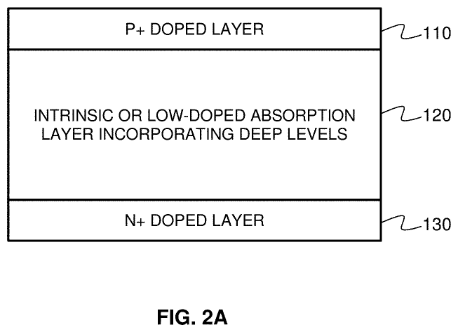

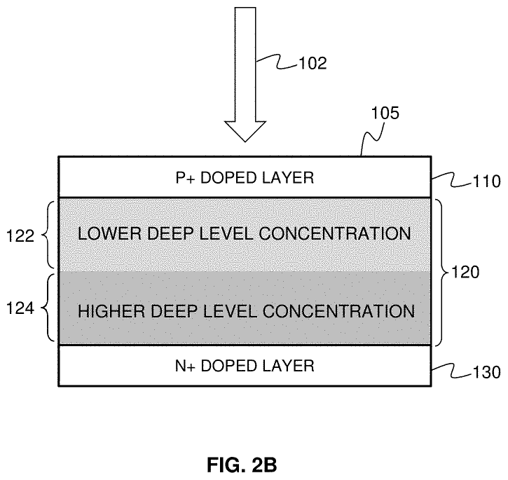

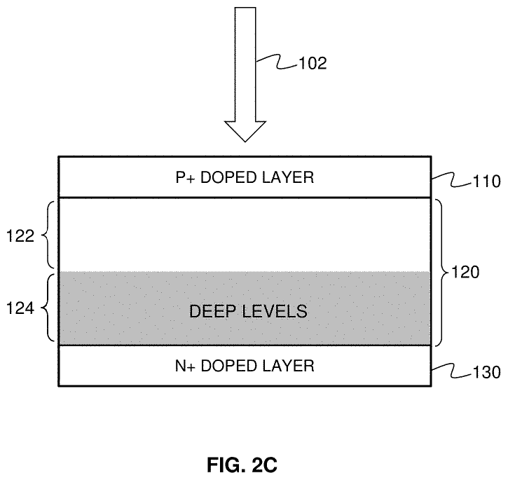

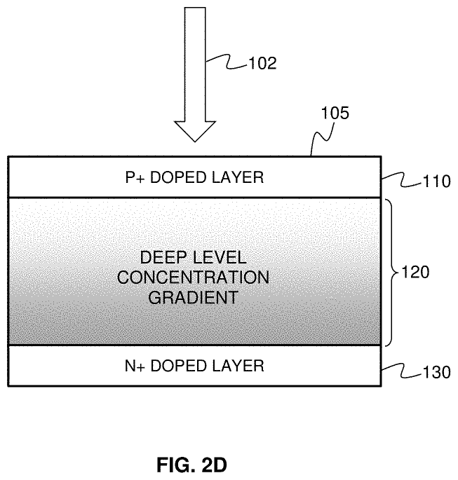

Accordingly, various example embodiments of the present disclosure provide avalanche photodetector devices that incorporate deep levels (e.g. mid-gap states) to further facilitate secondary carrier generation via impact ionization when detecting above-bandgap light. FIG. 2A illustrates an example implementation of a deep-level-assisted avalanche photodetector device that includes deep levels facilitating the generation of secondary carriers via impact ionization under application of a reverse bias. The example device includes p+ and n+ regions 110 and 130 and an intermediate semiconductor absorption region 120 that incorporates deep levels. When incident light, having photons with an energy exceeding a bandgap of the intermediate semiconductor absorption region 120 is incident on the device such that the absorption depth of the incident light extends into the intermediate semiconductor absorption region 120, a photocurrent is produced comprising photocarriers generated within the intermediate semiconductor absorption region and secondary carriers released from the deep levels via impact ionization. In some example embodiments, the respective device layers are formed from silicon.

While it is preferable for the incident light to be directed through an external surface that resides closest to the p+ doped layer 110, so that electron photocarriers are predominantly generated further from the n+ layer 130 and thus travel a longer distance and are more likely to undergo impact ionization, it will be understood that in other example implementations, the above-bandgap light may be incident laterally or through an external surface that is closest to the n+ doped layer.

The reverse bias may be applied such that a threshold of avalanche multiplication is achieved for electrons. The present inventors have found, for example, that a suitable reverse bias is one that results in an electric field within a range of 1×10⁵ to 1×10⁶ V/cm within a region proximal to the n+ region 130, when the APD is fabricated using silicon.

The incorporation of deep levels within an intermediate semiconductor region 120 of the avalanche photodetector device may be performed, for example, using processes compatible with standard semiconductor processing, such as ion implantation and annealing. For example, deep levels may be generated within silicon by ion implantation, which is a common fabrication process in the semiconductor industry. Chemically inert ions (such as hydrogen, helium, nitrogen, argon, silicon, germanium); or ions that could be chemically active if subjected to a post ion implantation high temperature anneal in excess of 800K (such as boron, phosphorus, arsenic) may be accelerated, for example, to an energy of between 1 and 4000 keV, and penetrate the silicon, creating lattice defects (which are electrical deep-levels typically greater than 3 times kT in energy from either the conduction or valence band, where k is Boltzmann's constant and T is temperature) through collisions with lattice atoms. The number of deep levels and their position depends on the energy, dose and mass of the accelerated ions. In some example implementations, ion implantation may be followed by a low-temperature (e.g. up to 600K) thermal treatment. Deep levels may also be introduced via low-temperature (less than 600K) deposition of material which may form the waveguide. Deep levels may also be introduced by subjecting a semiconductor to an inert plasma process. In some example implementations, the concentration of deep levels within an intermediate semiconductor region of the avalanche photodetector device may be between 1×10¹⁴ cm⁻³ and 1×10¹⁹ cm⁻³.

Without intending to be limited by theory, the ionization from the level within the bandgap may be preferentially initiated by electrons, depending on the method used to create the lattice perturbation. In such cases, a greater rate of initiation from electrons may results in a process that is less susceptible to added noise. For example, by judicious choice of the implanted ion, and/or the implantation does, and/or the implantation concentration, and/or the post implantation annealing recipe, it may be possible to change the ratio of electron to hole ionization coefficient.

Further, by pre-doping the semiconductor prior to formation of the APD, such that there is a background doping which is lightly n-type, here defined as having a background free electron concentration between 1×10¹⁴ and 1×10¹⁹ cm⁻³, deep-levels can be populated with an electron. This may further enhanced electron ionization compared to hole ionization.

In some example implementations, apart from the presence of deep levels, a semiconductor region within the avalanche photodetector device may be intrinsic (absent of shallow dopants) or be lightly doped with shallow dopants at concentrations less than 1×10¹⁹ cm⁻³.

FIG. 2B illustrates an example device configuration in which the deep levels are incorporated in a non-uniform manner relative to an external surface 105 that is configured to receive the incident light 102 (the figure schematically illustrates a non-limiting example implementation in which the external surface 105 is a top surface of the p+ doped layer, however, it will be understood that one or more intervening layers may reside between the external surface and the p+ layer, such as one or more antireflection layers). In the present example embodiment, the region 122 closest to the external surface 105 has a lower concentration of deep levels that a region 124 that is further from the external surface 105. In some example implementations, the region 122 may have a deep level concentration that is less than 1×10¹⁴ cm⁻³ and the region 124 may have a deep level concentration that exceeds 1×10¹⁴ cm⁻³. The deep level concentration with the region 124 may reside between 1×10¹⁴ cm⁻³ and 1×10¹⁹ cm⁻³.

FIG. 2C illustrates an example implementation in which only the region 124 that is furthest from the external surface 105 (that is configured to receive the incident light 102) is modified to include deep levels, while FIG. 2D illustrates an example implementation in which a concentration of deep levels within the intermediate semiconductor absorption layer 120 is graded such that the concentration increases with distance relative to the external surface 105.

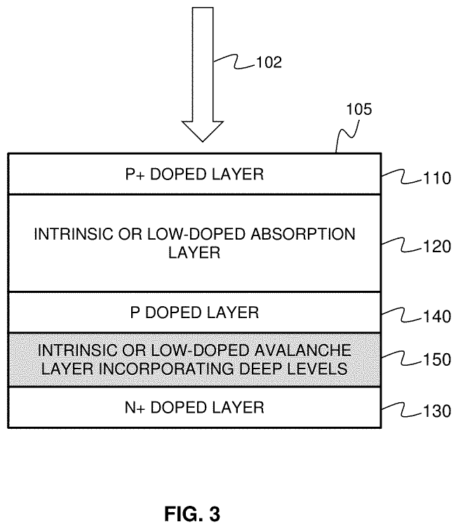

FIG. 3 illustrates an alternative example implementation of a deep-level-assisted avalanche photodetector device that incorporates separate semiconductor layers for absorption of incident light and for the generation of impact ionization. As shown in the figure, an intermediate semiconductor absorption layer 120 is provided between the p+ layer 110 and an additional p doped layer 140, where a dopant concentration of the p doped layer 140 is less than a dopant concentration of the p+ doped layer 110. The device is provided with appropriate layer thicknesses such that light 102 having a photon energy exceeding a bandgap of the intermediate semiconductor absorption layer 120, incident through an external surface 105, has an associated absorption depth that extends into the intermediate semiconductor absorption layer 120. Accordingly, absorption of the light within the intermediate semiconductor absorption layer 120 generates photocarriers that drift under the application of a reverse bias, and the reverse bias is selected such to prevent the onset of an avalanche effect within the intermediate semiconductor absorption layer 120. Primary electron photocarriers are thus injected, under the applied electric field associated with the reverse bias, into the semiconductor avalanche region 150, which includes deep levels that facilitate the generation of secondary carriers via impact ionization for a sufficiently high reverse bias. The thicknesses of the layers 120 and 150 may be selected such that when a threshold for avalanche multiplication via impact ionization is reached within the semiconductor avalanche layer 150, a corresponding threshold is not reached within the intermediate semiconductor absorption layer 120 (e.g. via generating a higher electric field within layer 150 than in layer 120).

While many of the preceding example embodiments have been illustrated in a configuration that favours the generation on an avalanche photocurrent via impact ionization of electrons, additional alternative example implementations that are configured to enhance hole-based impact ionization may be implemented by reversing the n and p regions in the preceding example embodiments.

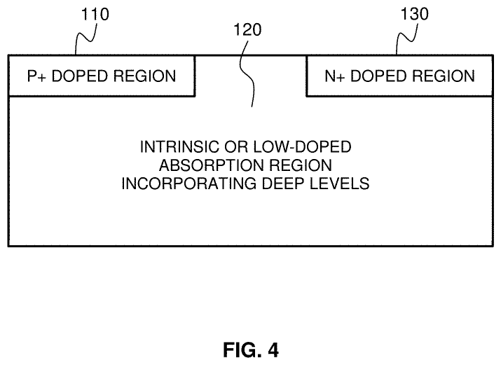

FIG. 4 illustrates an example embodiment of a deep-level-assisted avalanche photodetector device in which photocarrier drift and injection occurs, at least in part, laterally with respect to a device surface. As shown in the figure, an intermediate semiconductor absorption region 120 that includes deep levels provided between the p+ and n+ regions 110 and 120. The deep levels may be provided between and/or below the p+ and n+ doped regions 120 and 130. Photocarriers generated via absorption of above-bandgap light by the intermediate semiconductor absorption region 120 are subject to a lateral electric field under the application of a reverse bias and secondary carriers are generated, at least in part, by impact ionization events that release the secondary carriers from the deep levels.

While the preceding example embodiments have described silicon-based avalanche photodetector devices, in other example implementations, the semiconductor may be a semiconductor other than silicon, provided that a suitable deep level dopant is provided. Suitable examples of semiconductors and associated deep level dopants include, but are not limited to, germanium doped with sulfur or gallium arsenide doped with nickel, tin or cobalt.

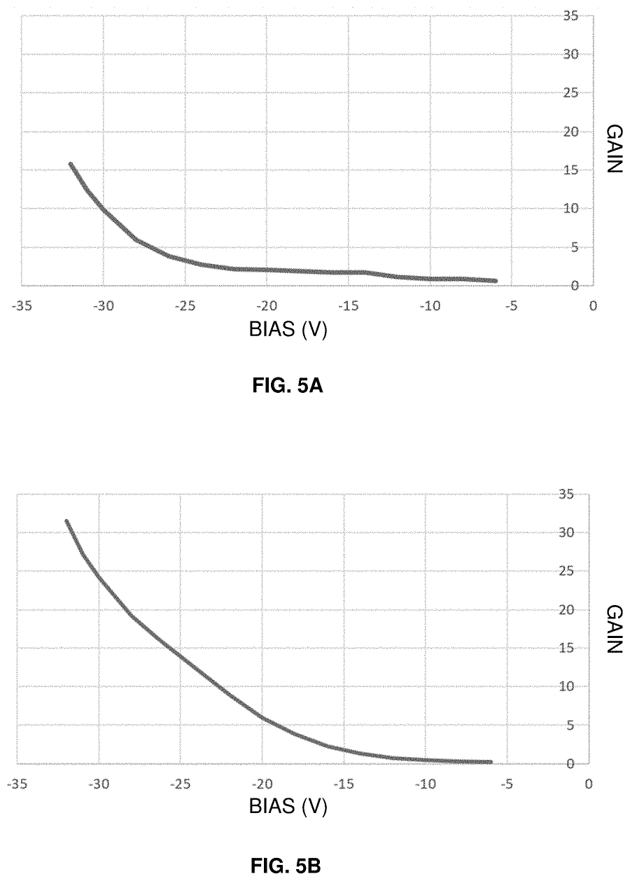

An example of the performance improvement that may be facilitated by the presence of the deep levels is presented in FIGS. 5A and 5B, which plot the measured internal responsivity for devices implanted with different concentrations of deep levels. The responsivity, which is defined as responsivity=photocurrent generated (Amps)/optical power absorbed (Watts), provides a normalized measurement of the APD performance and a responsivity above unity indicates gain (e.g. multiplication/amplification).

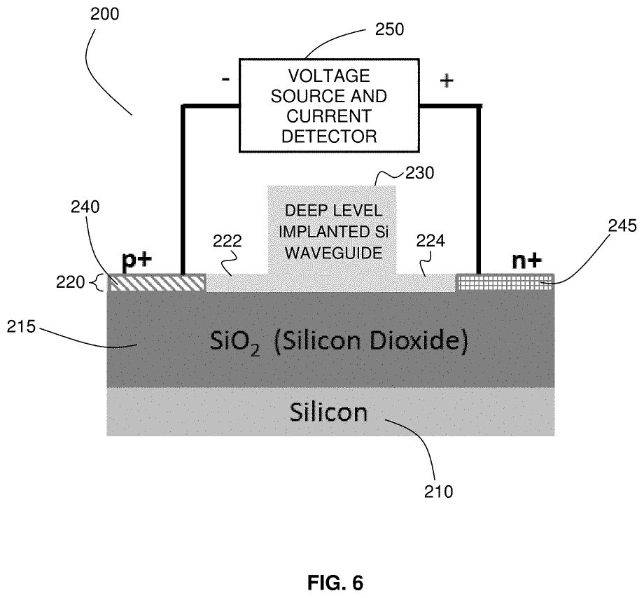

FIG. 5A shows the internal responsivity from a device implanted with deep levels via a dose of 3×10¹¹ cm⁻² while FIG. 5B plots the internal responsivity for a device implanted with a higher dose of 1×10¹² cm⁻². In this case the APD was of lateral geometry, and light was guided in a central waveguide region residing between the N+ and P+ regions. The example device 200 is schematically illustrated in FIG. 6, illustrating a silicon-on-insulator structure, in which a silicon substrate 210 supports a SiO₂ insulator layer 215, upon which a top silicon device layer 220 is provided. The central silicon waveguide 230 region is formed on the silicon device layer 220. The silicon waveguide 230 is doped with deep level impurities (e.g. substitutional impurities or lattice defects) that facilitates the excitation of photocarriers via the absorption of sub-bandgap light. As shown in the figure, p+ and n+ regions 240 and 245 are respectively provided on opposites sides of waveguide 230, in a manner suitable for applying an electric field within waveguide 230. The adjacent p+ and n+ regions 240 and 245, and silicon waveguide 230, together form a p-i-n junction (the “intrinsic” region being doped/implanted with deep level impurities). Metal electrodes (not shown) may be respectively formed over (or otherwise be brought into electrical communication with) the p+ and n+ regions 240 and 245, and the electrodes may be contacted, for example via bonded wires, to electrical circuitry 250 that includes, for example, a voltage source for generating a reverse bias (potential difference) and a current detector (e.g. amplifier circuit).

The device includes intrinsic offset regions 222 and 224 that laterally offset the respective p+ and n+ regions 224 and 224 from the central waveguide region 230. These lateral offset regions facilitate the generation of secondary carriers (avalanche multiplication) via impact ionization. In the present example implementation, both of the lateral offset regions 222 and 224 included deep levels, in addition to the central waveguide region 230.

The central optical waveguide 230 was 220 nm thick. The lateral offset regions 224 and 226 adjacent to the central optical waveguide 230 were 90 nm thick. The length of the device in which light was absorbed was 750 microns.

The deep levels were created by boron ion implantation at 70 keV followed by a post-implantation anneal at 200 C for 5 minutes. This process is expected to create vacancy-type defects which provide electrical deep-levels, approximately 0.4 eV below the conduction band edge. In the current measurement, sub-band gap light of wavelength 1550 nm was used to generate primary electrons and holes. It is expected that the generation of the electron hole pairs is decoupled from the deep level assisted avalanche process, and thus the deep level assisted process is equally applicable to sub-band gap light initiation, and greater than bandgap light initiation.

The two figures were generated under identical conditions, except that the lattice perturbations (deep levels) in the device of FIG. 5A were approximately 3.3 times less than those for the device of FIG. 5B. In the avalanche operation condition (>12 V reverse bias), the device implanted with a dose of 1×10¹² cm⁻² significantly outperformed the device implanted with a dose of 3×10¹¹ cm⁻² in terms of responsivity. It is noted that the ratio of responsivity for the two devices was approximately equal to the dose ratio.

In the present example implementation, deep levels were employed both (i) for the absorption of sub-bandgap light and (ii) to facilitate avalanche multiplication via the release of secondary carriers from the deep levels as a result of impact ionization. Accordingly, in some example embodiments, an absorption region of an avalanche photodetector device may include deep levels that facilitate the generation of photocarriers via the absorption of sub-bandgap light and an additional avalanche region may provided that includes deep levels that facilitate avalanche multiplication via the release of secondary carriers from the deep levels as a result of impact ionization. In a waveguide (or more generically, lateral) configuration such as that shown in FIG. 6, one or both of the lateral offset regions 222 and 224 may be provided with deep levels. It will be understood that this example embodiment may be adapted for multilayer vertical absorption devices, such that a first layer is provided that includes deep levels for the absorption of sub-bandgap light and a second layer is provided to facilitate avalanche multiplication via the release of secondary carriers from the deep levels as a result of impact ionization

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

Therefore what is claimed is:

1. A method of performing photodetection with an avalanche photodetector device, the method comprising:
providing an avalanche photodetector device comprising a p-doped semiconductor region, an n-doped semiconductor region, and an intermediate semiconductor absorption region residing between the n-doped semiconductor region and the p-doped semiconductor region, wherein at least one semiconductor region residing between the p-doped semiconductor region and the n-doped semiconductor region comprises deep levels;
while applying a reverse bias to the avalanche photodetector device, directing incident light onto the avalanche photodetector device, the incident light comprising photons having an energy exceeding a bandgap of the intermediate semiconductor absorption region, wherein an absorption depth of the incident light extends into the intermediate semiconductor absorption region, such that a photocurrent is produced comprising photocarriers generated within the intermediate semiconductor absorption region and secondary carriers released from the deep levels via impact ionization.

2. The method according to claim 1 wherein the p-doped semiconductor region is a p-doped semiconductor layer, the n-doped semiconductor region is an n-doped semiconductor layer, and the intermediate semiconductor absorption region is an intermediate semiconductor absorption layer.

3. The method according to claim 2 wherein the intermediate semiconductor absorption layer comprises at least a portion of the deep levels.

4. The method according to claim 3 wherein the incident light enters the avalanche photodetector device through an external surface, and wherein a concentration of deep levels within the intermediate semiconductor absorption layer is lower within a first portion of the intermediate semiconductor absorption layer that is closer to the external surface than within a second portion of the intermediate semiconductor absorption layer that is further from the external surface.

5. The method according to claim 4 wherein the first portion has a concentration of deep levels that is less than 1×10¹⁴ cm⁻³ and wherein the second portion has a concentration of deep levels that is greater than 1×10¹⁴ cm⁻³ and less than 1×10¹⁹ cm⁻³.

6. The method according to claim 2 wherein the p-doped semiconductor layer is a first p-doped semiconductor layer, and wherein the avalanche photodetector device further comprises:
a second p-doped semiconductor layer having a doping concentration less than the first p-doped layer, the second p-doped semiconductor layer residing between the n-doped semiconductor layer and the intermediate semiconductor absorption layer;
a semiconductor avalanche layer residing between the n-doped semiconductor layer and the second p-doped semiconductor layer;
wherein a thickness of the intermediate semiconductor absorption layer exceeds a thickness of the semiconductor avalanche layer, such that impact ionization occurs predominantly within the semiconductor avalanche layer; and
wherein the semiconductor avalanche layer comprises at least a portion of the deep levels.

7. The method according to claim 6 wherein a concentration of deep levels in the semiconductor avalanche layer exceeds a concentration of deep levels in the intermediate semiconductor absorption layer.

8. The method according to claim 6 wherein a concentration of the deep levels within the semiconductor avalanche layer lies between 1×10¹⁴ cm⁻³ and 1×10¹⁹ cm⁻³.

9. The method according to claim 6 wherein a concentration of the deep levels within the intermediate semiconductor absorption layer is less than 1×10¹⁴ cm⁻³.

10. The method according to claim 6 wherein the incident light is incident on the avalanche photodetector device through an external surface that is closer to the intermediate semiconductor absorption layer than to the semiconductor avalanche layer.

11. The method according to claim 6 wherein the incident light is incident on the avalanche photodetector device such that the incident light encounters the intermediate semiconductor absorption layer without first passing through the semiconductor avalanche layer.

12. The method according to claim 1 wherein a concentration of the deep levels within the at least one semiconductor region lies between 1×10¹⁴ cm⁻³ and 1×10¹⁹ cm⁻³

13. The method according to claim 1 wherein the p-doped semiconductor region is laterally offset from the n-doped semiconductor region, such that at least a portion of the intermediate semiconductor absorption region resides between the p-doped semiconductor region and the n-doped semiconductor region.

14. An avalanche photodetector device comprising:
a p-doped semiconductor layer;
an n-doped semiconductor layer; and
an intermediate semiconductor absorption layer residing between said n-doped semiconductor layer and said p-doped semiconductor layer;
wherein at least one semiconductor region residing between said p-doped semiconductor layer and said n-doped semiconductor layer comprises deep levels, such that when incident light having a photon energy exceeding a band gap of said intermediate semiconductor absorption layer is directed onto said avalanche photodetector device and a suitable reverse bias is applied to said avalanche photodetector device, a photocurrent is produced comprising photocarriers generated within said intermediate semiconductor absorption layer and secondary carriers released from the deep levels via impact ionization.

15. The device according to claim 14 wherein said intermediate semiconductor absorption layer comprises at least a portion of said deep levels.

16. The device according to claim 15 further comprising an external surface configured to receive the incident light, wherein a concentration of deep levels within said intermediate semiconductor absorption layer is lower within a first portion of said intermediate semiconductor absorption layer that is closer to said external surface than within a second portion of said intermediate semiconductor absorption layer that is further from said external surface.

17. The device according to claim 16 wherein said first portion has a concentration of deep levels that is less than 1×10¹⁴ cm⁻³ and wherein said second portion has a concentration of deep levels that is greater than 1×10¹⁴ cm⁻³ and less than 1×10¹⁹ cm⁻³.

18. The device according to claim 14 wherein said p-doped semiconductor layer is a first p-doped semiconductor layer, and wherein said avalanche photodetector device further comprises:
a second p-doped semiconductor layer having a doping concentration less than said first p-doped layer, said second p-doped semiconductor layer residing between said n-doped semiconductor layer and said intermediate semiconductor absorption layer;
a semiconductor avalanche layer residing between said n-doped semiconductor layer and said second p-doped semiconductor layer;
wherein a thickness of said intermediate semiconductor absorption layer exceeds a thickness of said semiconductor avalanche layer, such that impact ionization occurs predominantly within said semiconductor avalanche layer under application of the suitable reverse bias; and
wherein said semiconductor avalanche layer comprises at least a portion of said deep levels.

19. The device according to claim 18 wherein a concentration of deep levels in said semiconductor avalanche layer exceeds a concentration of deep levels in said intermediate semiconductor absorption layer.

20. The device according to claim 18 wherein a concentration of said deep levels within said semiconductor avalanche layer lies between 1×10¹⁴ cm⁻³ and 1×10¹⁹ cm⁻³.

21. The device according to claim 18 wherein a concentration of said deep levels within said intermediate semiconductor absorption layer is less than 1×10¹⁹ cm⁻³

22. The device according to claim 18 further comprising an external surface configured to receive the incident light, wherein said external surface is closer to said intermediate semiconductor absorption layer than to said semiconductor avalanche layer.

23. The device according to claim 14 wherein a concentration of said deep levels within said at least one semiconductor region lies between 1×10¹⁴ cm⁻³ and 1×10¹⁹ cm⁻³.

24. A method of performing photodetection with an avalanche photodetector device, the method comprising:
providing an avalanche photodetector device comprising a p-doped semiconductor region, an n-doped semiconductor region, and an intermediate semiconductor absorption region residing between the n-doped semiconductor region and the p-doped semiconductor region, and an avalanche semiconductor region residing between the n-doped semiconductor region and the p-doped semiconductor region, wherein the intermediate semiconductor absorption region and the avalanche semiconductor region each comprise deep levels;
while applying a reverse bias to the avalanche photodetector device, directing incident light onto the avalanche photodetector device, the incident light comprising photons having an energy less than a bandgap of the intermediate semiconductor absorption region, wherein an absorption depth of the incident light extends into the intermediate semiconductor absorption region, such that a photocurrent is produced comprising photocarriers generated by deep-level-mediated absorption within the intermediate semiconductor absorption region and by secondary carriers released from the deep levels within the avalanche semiconductor region via impact ionization.

25. An avalanche photodetector device comprising:
a p-doped semiconductor layer;
an n-doped semiconductor layer;
an intermediate semiconductor absorption layer residing between said n-doped semiconductor layer and said p-doped semiconductor layer; and
a semiconductor avalanche layer residing between said n-doped semiconductor layer and said p-doped semiconductor layer;
wherein said intermediate semiconductor absorption layer and said semiconductor avalanche layer comprise deep levels, such that when incident light having a photon energy less than a band gap of said intermediate semiconductor absorption layer is directed onto said avalanche photodetector device and a suitable reverse bias is applied to said avalanche photodetector device, a photocurrent is produced comprising photocarriers generated via deep-level-mediated absorption within said intermediate semiconductor absorption layer and by secondary carriers released from the deep levels via impact ionization within said semiconductor avalanche layer.
